(19) United States
(12) Patent Application Publication
(10) Pub. No.: US 2024/0405496 A1
(43) Pub. Date: Dec. 5, 2024

(54) CHAMBER FOR GAS LASER DEVICE, GAS LASER DEVICE, AND ELECTRONIC DEVICE MANUFACTURING METHOD

(71) Applicant: Gigaphoton Inc., Tochigi (JP)

(72) Inventors: Yoichi SASAKI, Oyama-shi (JP); Junichi FUJIMOTO, Oyama-shi (JP); Jeffrey P. SERCEL, Manchester, NH (US); Michael von DADELSZEN, Manchester, NH (US)

(73) Assignee: Gigaphoton Inc., Tochigi (JP)

(21) Appl. No.: 18/799,414

(22) Filed: Aug. 9, 2024

Related U.S. Application Data
(63) Continuation of application No. PCT/JP2023/004032, filed on Feb. 7, 2023.
(60) Provisional application No. 63/269,937, filed on Mar. 25, 2022.

(51) Int. Cl. H01S 3/038; G03F 7/20

(52) U.S. Cl. CPC H01S 3/0384; H01S 3/0385; H01S 3/0388; G03F 7/2006

(57) ABSTRACT

A chamber for a gas laser device includes a first main electrode and a second main electrode arranged along a predetermined direction as being apart from and facing each other in the internal space, a window arranged at a wall surface of the chamber and transmitting light from the internal space, and a first preionization electrode arranged beside one side of the first main electrode. Here, the first preionization electrode includes a first dielectric pipe, a first preionization inner electrode arranged in the first dielectric pipe and extending along the first dielectric pipe, and a first preionization outer electrode extending along the first dielectric pipe and including a first end portion facing the first dielectric pipe with a first gap with respect to the first dielectric pipe. At least a part of the first gap is larger than 0 mm and equal to or smaller than 0.9 mm.

### CROSS-REFERENCE TO RELATED APPLICATIONS

The present application claims the benefit of International Application No. PCT/JP2023/004032, filed on Feb. 7, 2023, the entire contents of which are hereby incorporated by reference.

### BACKGROUND

### 1. Technical Field

The present disclosure relates to a chamber for a gas laser device, a gas laser device, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 μm to 400 μm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be narrowed to the extent that the chromatic aberration can be ignored. For this purpose, there is a case in which a line narrowing module (LNM) including a line narrowing element (etalon, grating, and the like) is provided in a laser resonator of the gas laser device to narrow a spectral line width. In the following, a gas laser device with a narrowed spectral line width is referred to as a line narrowing gas laser device.

### LIST OF DOCUMENTS

### Patent Documents

Patent Document 1: U.S. Pat. No. 6,535,540
Patent Document 2: U.S. Pat. No. 5,708,676

### SUMMARY

A chamber, according to an aspect of the present disclosure, for a gas laser device has an internal space at which a laser gas is enclosed. The chamber includes a first main electrode and a second main electrode arranged with a longitudinal direction thereof being along a predetermined direction as being apart from and facing each other in the internal space, a window arranged at a wall surface of the chamber and configured to transmit light from the internal space, and a first preionization electrode arranged beside one side of the first main electrode. Here, the first preionization electrode includes a first dielectric pipe, a first preionization inner electrode arranged in the first dielectric pipe and extending along a longitudinal direction of the first dielectric pipe, and a first preionization outer electrode extending along the longitudinal direction of the first dielectric pipe and including a first end portion facing the first dielectric pipe with a first gap with respect to the first dielectric pipe. At least a part of the first gap is larger than 0 mm and equal to or smaller than 0.9 mm.

A gas laser device, according to an aspect of the present disclosure, includes a chamber having an internal space at which a laser gas is enclosed. Here, the chamber includes a first main electrode and a second main electrode arranged with a longitudinal direction thereof being along a predetermined direction as being apart from and facing each other in the internal space, a window arranged at a wall surface of the chamber and configured to transmit light from the internal space, and a first preionization electrode arranged beside one side of the first main electrode. The first preionization electrode includes a first dielectric pipe, a first preionization inner electrode arranged in the first dielectric pipe and extending along a longitudinal direction of the first dielectric pipe, and a first preionization outer electrode extending along the longitudinal direction of the first dielectric pipe and including a first end portion facing the first dielectric pipe with a first gap with respect to the first dielectric pipe. At least a part of the first gap is larger than 0 mm and equal to or smaller than 0.9 mm.

An electronic device manufacturing method according to an aspect of the present disclosure includes generating laser light using a gas laser device including a chamber having an internal space at which a laser gas is enclosed, outputting the laser light to an exposure apparatus, and exposing a photosensitive substrate to the laser light in the exposure apparatus to manufacture an electronic device. Here, the chamber includes a first main electrode and a second main electrode arranged with a longitudinal direction thereof being along a predetermined direction as being apart from and facing each other in the internal space, a window arranged at a wall surface of the chamber and configured to transmit light from the internal space, and a first preionization electrode arranged beside one side of the first main electrode. The first preionization electrode includes a first dielectric pipe, a first preionization inner electrode arranged in the first dielectric pipe and extending along a longitudinal direction of the first dielectric pipe, and a first preionization outer electrode extending along the longitudinal direction of the first dielectric pipe and including a first end portion facing the first dielectric pipe with a first gap with respect to the first dielectric pipe. At least a part of the first gap is larger than 0 mm and equal to or smaller than 0.9 mm.

### BRIEF DESCRIPTION OF THE DRAWINGS

Embodiments of the present disclosure will be described below merely as examples with reference to the accompanying drawings.

FIG. 1 is a schematic view showing a schematic configuration example of an entire electronic device manufacturing apparatus.

FIG. 2 is a schematic view showing a schematic configuration example of an entire gas laser device of a comparative example.

FIG. 3 is a sectional view, perpendicular to a travel direction of laser light, of a chamber of the comparative example.

FIG. 4 is a top view of the vicinity of a first main electrode shown in FIG. 3.

FIG. 5 is an electrical circuit diagram of the chamber of the comparative example.

FIG. 6 is a view showing the vicinity of a preionization electrode of a first embodiment along a Z direction.

FIG. 7 is a top view of the vicinity of the preionization electrode shown in FIG. 6.

FIG. 8 is a graph showing the relationship between the dimension of a first gap and a light emission area of ultraviolet light between a first dielectric pipe and a first end portion.

FIG. 9 is an electrical circuit diagram of the chamber of a first modification of the first embodiment.

FIG. 10 is s a view showing the vicinity of the preionization electrode of a second modification of the first embodiment along the Z direction.

FIG. 11 is an electrical circuit diagram of the chamber of the second modification of the first embodiment.

FIG. 12 is a view showing the vicinity of the preionization electrode of a second embodiment along the Z direction.

FIG. 13 is a top view of the vicinity of the preionization electrode shown in FIG. 12.

FIG. 14 is a perspective view of the vicinity of a cutout and a spacer to be fixed to the cutout of the second embodiment.

FIG. 15 is a perspective view of the spacer fixed to the cutout shown in FIG. 14.

FIG. 16 is a perspective view of the vicinity of the cutout and the spacer to be fixed to the cutout according to a modification of the second embodiment.

FIG. 17 is a perspective view of the spacer fixed to the cutout shown in FIG. 16.

FIG. 18 is a top view of the vicinity of the preionization electrode of a third embodiment.

FIG. 19 is a view showing the vicinity of the preionization electrode of a fourth embodiment along the Z direction.

FIG. 20 is an electrical circuit diagram of the chamber of the fourth embodiment.

FIG. 21 is a view showing the vicinity of the preionization electrode of a fifth embodiment along the Z direction.

FIG. 22 is a top view of the vicinity of the first preionization electrode shown in FIG. 21.

FIG. 23 is an electrical circuit diagram of the chamber of the fifth embodiment.

FIG. 24 is a top view of the vicinity of a first and third preionization electrodes of a modification of the fifth embodiment.

### DESCRIPTION OF EMBODIMENTS

1. Description of electronic device manufacturing apparatus used in exposure process for electronic device
2. Description of gas laser device of comparative example
   2.1 Configuration
   2.2 Operation
   2.3 Problem
3. Description of chamber of first embodiment
   3.1 Configuration
   3.2 Effect
4. Description of chamber of second embodiment
   4.1 Configuration
   4.2 Effect
5. Description of chamber of third embodiment
   5.1 Configuration
   5.2 Effect
6. Description of chamber of fourth embodiment
   6.1 Configuration
   6.2 Effect
7. Description of chamber of fifth embodiment
   7.1 Configuration
   7.2 Effect

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Description of Electronic Device Manufacturing Apparatus Used in Exposure Process for Electronic Device

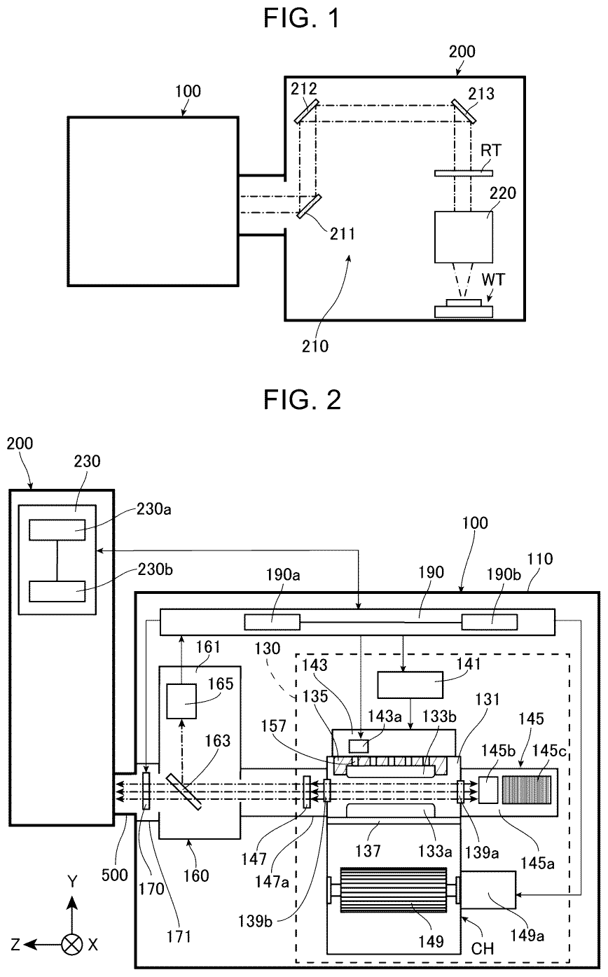

FIG. 1 is a schematic view showing a schematic configuration example of an entire electronic device manufacturing apparatus used in an exposure process for an electronic device. As shown in FIG. 1, the manufacturing apparatus used in the exposure process includes a gas laser device 100 and an exposure apparatus 200. The exposure apparatus 200 includes an illumination optical system 210 including a plurality of mirrors 211, 212, 213 and a projection optical system 220. The illumination optical system 210 illuminates a reticle pattern of a reticle stage RT with laser light incident from the gas laser device 100. The projection optical system 220 causes the laser light transmitted through the reticle to be imaged as being reduced and projected on a workpiece (not shown) arranged on a workpiece table WT. The workpiece is a photosensitive substrate such as a semiconductor wafer on which photoresist is applied. The exposure apparatus 200 synchronously translates the reticle stage RT and the workpiece table WT to expose the workpiece to the laser light reflecting the reticle pattern. Through the exposure process as described above, a device pattern is transferred onto the semiconductor wafer, thereby a semiconductor device, which is the electronic device, can be manufactured.

### 2. Description of Gas Laser Device of Comparative Example

### 2.1 Configuration

The gas laser device 100 of a comparative example will be described. The comparative example of the present disclosure is an example recognized by the applicant as known only by the applicant, and is not a publicly known example admitted by the applicant.

FIG. 2 is a schematic view showing a schematic configuration example of the entire gas laser device 100 of the comparative example. The gas laser device 100 is, for example, an ArF excimer laser device using a mixed gas including argon (Ar), fluorine (_{F2}), and neon (Ne). The gas laser device 100 outputs laser light having a center wavelength of about 193 nm. Here, the gas laser device 100 may be a gas laser device other than the ArF excimer laser device, and may be, for example, a KrF excimer laser device using a mixed gas including krypton (Kr), F₂, and Ne. In this case, the gas laser device 100 outputs laser light having a center wavelength of about 248 nm. The mixed gas containing Ar, F₂, and Ne which is a laser medium and the mixed gas containing Kr, F₂, and Ne which is a laser medium may be each referred to as a laser gas.

The gas laser device 100 includes a housing 110, and a laser oscillator 130, a monitor module 160, a shutter 170, and a laser processor 190 arranged at the internal space of the housing 110 as a main configuration.

The laser oscillator 130 includes a chamber device CH, a charger 141, a pulse power module 143, a line narrowing module 145, and an output coupling mirror 147. In FIG. 2, the internal configuration of the chamber device CH is shown as viewed from a direction substantially perpendicular to the travel direction of the laser light.

Examples of the material of a chamber 131 of the chamber device CH include a metal such as nickel-plated aluminum and nickel-plated stainless steel. The chamber 131 includes an internal space in which light is generated by excitation of a laser medium in the laser gas. The light travels toward windows 139a, 139b described later. The laser gas is supplied from a laser gas supply source (not shown) to the internal space of the chamber 131 through a pipe (not shown). Further, the laser gas in the chamber 131 is subjected to a process of removing an Fe gas by a halogen filter or the like, and is exhausted to the outside of the housing 110 through a pipe (not shown) by an exhaust pump (not shown).

At the internal space of the chamber 131, an electrode 133a which is a first main electrode and an electrode 133b which is a second main electrode are spaced apart from and face each other, and each longitudinal direction is along the travel direction of the laser light. In the following, the longitudinal direction of the electrodes 133a, 133b may be referred to as a Z direction, the direction which is perpendicular to the Z direction and in which the electrodes 133a, 133b are juxtaposed and the electrodes 133a, 133b are spaced apart from each other may be referred to as a Y direction, and the direction perpendicular to the Y direction and the Z direction may be referred to as an X direction. The electrodes 133a, 133b are discharge electrodes for exciting the laser medium by glow discharge. In the present example, the electrode 133a is the anode and the electrode 133b is the cathode.

The electrode 133a is supported by and electrically connected to an electrode holder portion 137. The electrode 133b is fixed to a surface of a plate-shaped electrical insulating portion 135 on a side facing the internal space of the chamber 131 by a conductive member 157 which is, for example, a bolt. The conductive member 157 is electrically connected to the pulse power module 143, and applies a high voltage from the pulse power module 143 to the electrode 133b.

The electrical insulating portion 135 includes an insulator. Examples of the material of the electrical insulating portion 135 include alumina ceramics having low reactivity with an Fe gas. The electrical insulating portion 135 may have electrical insulation, and the material of the electrical insulating portion 135 may be a resin such as a phenol resin and a fluoro-resin, or quartz, glass, or the like. The electrical insulating portion 135 blocks an opening provided in the chamber 131 and is fixed to the chamber 131.

The charger 141 is a DC power source device that charges a charging capacitor (not shown) in the pulse power module 143 with a predetermined voltage. The pulse power module 143 includes a switch 143a controlled by the laser processor 190. When the switch 143a is turned ON from OFF, the pulse power module 143 generates a pulse high voltage from the electric energy charged in the charging capacitor and applies the high voltage between the electrode 133a and the electrode 133b.

When the high voltage is applied between the electrode 133a and the electrode 133b, discharge occurs between the electrode 133a and the electrode 133b. The laser medium in the chamber 131 is excited by the energy of the discharge, and the excited laser medium emits light when shifting to the ground state.

A pair of windows 139a, 139b are arranged on a wall surface of the chamber 131. The window 139a is located at one end side of the chamber 131 in the travel direction of the laser light, the window 139b is located at the other end side in the travel direction, and the windows 139a, 139b sandwich a space between the electrode 133a and the electrode 133b. The windows 139a, 139b are inclined at the Brewster angle with respect to the travel direction of the laser light so that P-polarized light of the laser light is suppressed from being reflected. The laser light oscillated as described later is output to the outside of the chamber 131 through the windows 139a, 139b.

The line narrowing module 145 includes a housing 145a, a prism 145b arranged at the internal space of the housing 145a, a grating 145c, and a rotation stage (not shown). An opening is formed in the housing 145a, and the housing 145a is connected to the rear side of the chamber 131 through the opening.

The prism 145b expands the beam width of the light output from the window 139a and causes the light to be incident on the grating 145c. Further, the prism 145b also reduces the beam width of the reflection light from the grating 145c and returns the light to the internal space of the chamber 131 through the window 139a. The prism 145b is supported by the rotation stage and is rotated by the rotation stage. The incident angle of the light with respect to the grating 145c is changed by the rotation of the prism 145b. Therefore, by rotating the prism 145b, the wavelength of the light returning from the grating 145c to the chamber 131 via the prism 145b can be selected. Although FIG. 2 shows an example in which one prism 145b is arranged, at least one prism may be arranged.

The surface of the grating 145c is configured of a material having a high reflectance, and a large number of grooves are formed on the surface at predetermined intervals. The cross sectional shape of each groove is, for example, a right triangle. The light incident on the grating 145c from the prism 145b is diffracted in a direction corresponding to the wavelength of the light when reflected by the grooves. The grating 145c is arranged in the Littrow arrangement, which causes the incident angle of the light incident on the grating 145c from the prism 145b to coincide with the diffraction angle of the diffracted light having a desired wavelength. Thus, light having a wavelength close to the desired wavelength returns into the chamber 131 via the prism 145b.

The output coupling mirror 147 is arranged at the internal space of an optical path pipe 147a connected to the front side of the chamber 131, and faces the window 139b. The output coupling mirror 147 transmits a part of the laser light output from the window 139b toward the monitor module 160, and reflects another part of the laser light to return to the internal space of the chamber 131 through the window 139b. Thus, the grating 145c and the output coupling mirror 147 configure a Fabry-Perot laser resonator, and the chamber 131 is arranged on the optical path of the laser resonator.

The monitor module 160 is arranged on the optical path of the laser light output from the output coupling mirror 147. The monitor module 160 includes a housing 161, and a beam splitter 163 and an optical sensor 165 arranged at the internal space of the housing 161. An opening is formed in the housing 161, and the internal space of the housing 161 communicates with the internal space of the optical path pipe 147a through the opening.

The beam splitter 163 transmits a part of the laser light output from the output coupling mirror 147 toward the shutter 170, and reflects another part of the laser light toward a light receiving surface of the optical sensor 165. The optical sensor 165 measures an energy E of the laser light incident on the light receiving surface, and outputs a signal indicating the measured energy E to the laser processor 190.

The laser processor 190 of the present disclosure is a processing device including a storage device 190a in which a control program is stored and a central processing unit (CPU) 190b that executes the control program. The laser processor 190 is specially configured or programmed to perform various processes included in the present disclosure. The laser processor 190 controls the entire gas laser device 100.

The laser processor 190 transmits and receives various signals to and from an exposure processor 230 of the exposure apparatus 200. For example, the laser processor 190 receives a later-described light emission trigger Tr and a later-described target energy Et from the exposure processor 230. The target energy Et is a target value of the energy of the laser light used in the exposure process. The laser processor 190 controls the charge voltage of the charger 141 based on the energy E and the target energy Et received from the optical sensor 165 and the exposure processor 230, respectively. By controlling the charge voltage, the energy of the laser light is controlled. Further, the laser processor 190 transmits a command signal of ON or OFF of the switch 143a to the pulse power module 143. The laser processor 190 is electrically connected to the shutter 170 and controls opening and closing of the shutter 170.

The laser processor 190 closes the shutter 170 until a difference ΔE between the energy E received from the monitor module 160 and the target energy Et received from the exposure processor 230 falls within an allowable range. When the difference ΔE falls within the allowable range, the laser processor 190 transmits, to the exposure processor 230, a reception preparation completion signal indicating that reception preparation of the light emission trigger Tr is completed. The exposure processor 230 transmits a signal indicating the light emission trigger Tr to the laser processor 190 when receiving the reception preparation completion signal, and the laser processor 190 opens the shutter 170 when receiving the signal indicating the light emission trigger Tr. The light emission trigger Tr is defined by a predetermined repetition frequency f and a predetermined number of pulses P of the laser light, is a timing signal for the exposure processor 230 to cause the laser oscillator 130 to perform laser oscillation, and is an external trigger. The repetition frequency f of the laser light is, for example, 100 Hz or more and 10 kHz or less.

The shutter 170 is arranged on the optical path of the laser light at the internal space of an optical path pipe 171 communicating with an opening formed at the housing 161 of the monitor module 160 on a side opposite to the side to which the optical path pipe 147a is connected. The internal spaces of the optical path pipes 171, 147a and the internal spaces of the housings 161, 145a are supplied and filled with a purge gas. The purge gas includes an inert gas such as nitrogen (N₂). The purge gas is supplied from a purge gas supply source (not shown) through a pipe (not shown). The optical path pipe 171 is in communication with the exposure apparatus 200 through the opening of the housing 110 and the optical path pipe 500 connecting the housing 110 and the exposure apparatus 200. The laser light having passed through the shutter 170 enters the exposure apparatus 200.

The exposure processor 230 of the present disclosure is a processing device including a storage device 230a in which a control program is stored and a CPU 230b that executes the control program. The exposure processor 230 is specifically configured or programmed to perform various processes included in the present disclosure. Further, the exposure processor 230 controls the entire exposure apparatus 200.

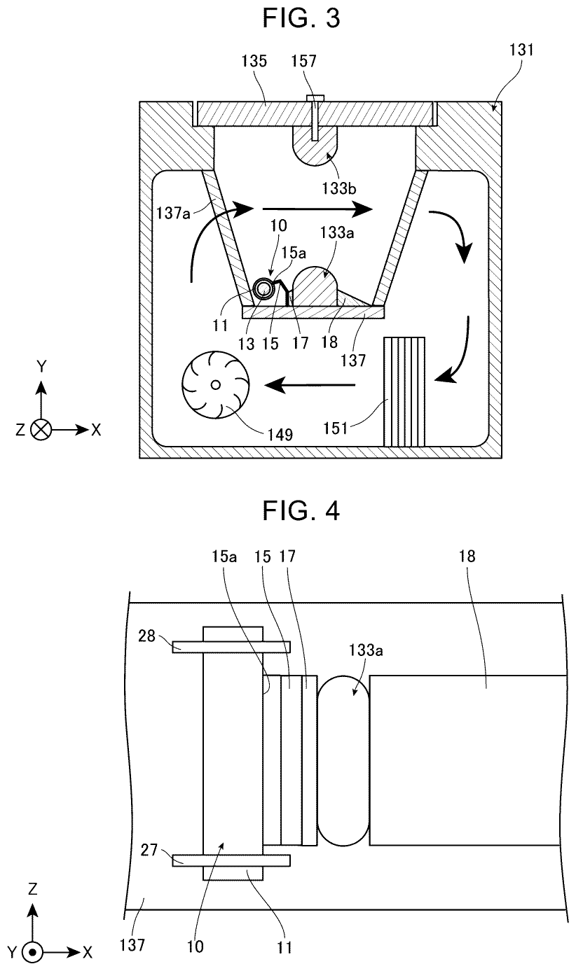

FIG. 3 is a sectional view, perpendicular to the travel direction of the laser light, of the chamber 131 of the comparative example. FIG. 4 is a top view of the vicinity of the electrode 133a shown in FIG. 3. A cross flow fan 149 and a heat exchanger 151 are further arranged at the internal space of the chamber 131.

The cross flow fan 149 and the heat exchanger 151 are arranged on a side opposite to the electrode 133a with respect to the electrode holder portion 137. At the internal space of the chamber 131, the space in which the cross flow fan 149 and the heat exchanger 151 are arranged is in communication with the space between the electrode 133a and the electrode 133b. The heat exchanger 151 is a radiator arranged beside the cross flow fan 149 and connected to a pipe (not shown) through which a cooling medium, which is a liquid or a gas, flows. As shown in FIG. 2, the cross flow fan 149 is connected to a motor 149a arranged outside the chamber 131, and rotates with rotation of the motor 149a. As the cross flow fan 149 rotates, the laser gas enclosed at the internal space of the chamber 131 circulates as indicated by bold arrows in FIG. 3. That is, the laser gas circulates through the cross flow fan 149, a space between the electrode 133a and the electrode 133b, the heat exchanger 151, and the cross flow fan 149 in this order. At least a part of the circulating laser gas passes through the heat exchanger 151, and the temperature of the laser gas is adjusted by the heat exchanger 151. Due to circulation of the laser gas, impurities of the laser gas generated by main discharge between the electrode 133a and the electrode 133b move downstream, and a fresh laser gas is supplied between the electrode 133a and the electrode 133b for subsequent discharge. Further, when the laser gas passes through the heat exchanger 151, heat caused by main discharge is removed, and an increase in temperature of the laser gas is suppressed. ON/OFF and the number of revolution of the motor 149a are controlled by the laser processor 190. Accordingly, the laser processor 190 can adjust the circulation speed of the laser gas circulating through the internal space of the chamber 131 by controlling the motor 149a.

The electrode holder portion 137 is electrically connected to the chamber 131 via wirings 137a. The electrode 133a supported by the electrode holder portion 137 is connected to the ground potential via the electrode holder portion 137, the wirings 137a, and the chamber 131.

A preionization electrode 10 is provided on the electrode holder portion 137 beside the electrode 133a. The preionization electrode 10 is arranged upstream of the laser gas flowing between the electrode 133a and the electrode 133b in the X direction. The preionization electrode 10 includes a dielectric pipe 11, a preionization inner electrode, and a preionization outer electrode. Hereinafter, each of the preionization inner electrode and the preionization outer electrode may be referred to as an inner electrode 13 and an outer electrode 15.

The dielectric pipe 11 has, for example, a cylindrical shape, and is arranged with the longitudinal direction thereof oriented along the Z direction. Examples of the material of the dielectric pipe 11 include alumina ceramics and sapphire.

The inner electrode 13 has a rod shape, is arranged inside the dielectric pipe 11, and extends along the longitudinal direction of the dielectric pipe 11. Examples of the material of the inner electrode 13 include copper and brass.

The outer electrode 15 is arranged between the dielectric pipe 11 and the electrode 133a, and extends along the longitudinal direction of the dielectric pipe 11. The outer electrode 15 includes an end portion 15a that faces a part of the outer circumference surface of the dielectric pipe 11. The end portion 15a is arranged from one end to the other end of the outer electrode 15 in the longitudinal direction of the outer electrode 15. The outer electrode 15 is bent in an in-plane direction perpendicular to the longitudinal direction of the dielectric pipe 11, and due to the bending, the end portion 15a is in contact with the outer circumference surface of the dielectric pipe 11 so as to push the outer circumference surface of the dielectric pipe 11. As shown in FIG. 4, the end portion 15a is in contact with the outer circumference surface of the dielectric pipe 11 over the entire length in the Z direction. A screw hole (not shown) is provided at an end portion of the outer electrode 15 on a side opposite to the end portion 15a, and the outer electrode 15 is fixed to a guide 17 by a screw (not shown) screwed into the screw hole. The guide 17 is fixed to the electrode 133a. Therefore, it can be understood that the outer electrode 15 is fixed to the electrode 133a via the guide 17. Here, the outer electrode 15 may be directly fixed to the electrode 133a. Examples of the material of the outer electrode 15 include copper and brass.

On the electrode holder portion 137, a guide 18 is further arranged beside the electrode 133a on a side opposite to the guide 17. Thus, the electrode 133a is sandwiched between the guides 17, 18. The guides 17, 18 guide the laser gas so that the laser gas from the cross flow fan 149 flows between the electrode 133a and the electrode 133b. Examples of the material of the guides 17, 18 include a porous nickel metal having low reactivity with an F₂ gas.

As shown in FIG. 4, a pair of holders 27, 28 are fixed on the electrode holder portion 137 beside the electrode 133a. One end of the dielectric pipe 11 is inserted to a hole (not shown) of the holder 27, and the other end of the dielectric pipe 11 is inserted to a hole (not shown) of the holder 28. Thus, the dielectric pipe 11 is held by the holders 27, 28.

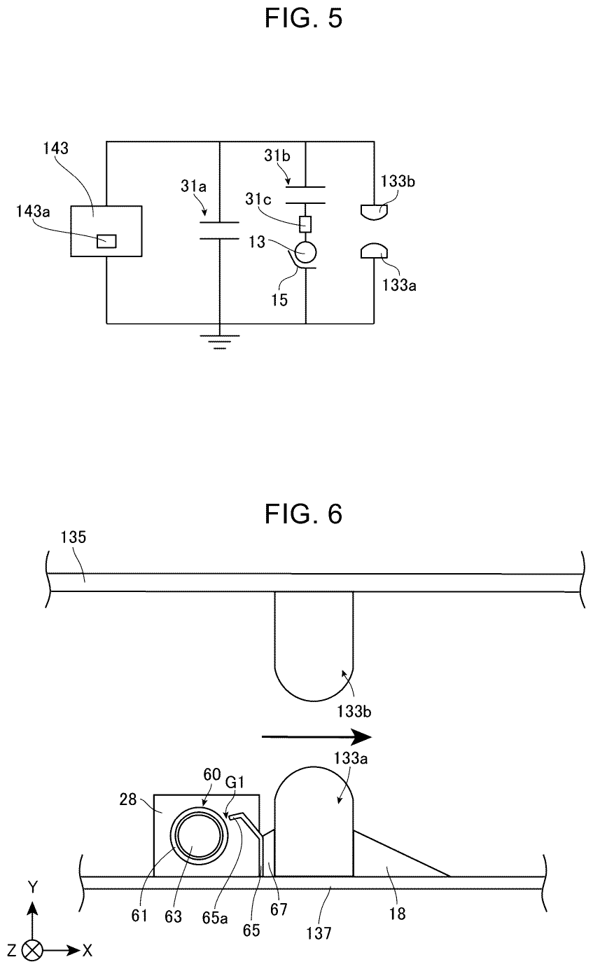

FIG. 5 is an electrical circuit diagram of the chamber 131 of the comparative example. Further, a peaking capacitor 31a and a preionization capacitor 31b are arranged at the chamber 131. The inner electrode 13 is electrically connected to one end of the preionization capacitor 31b via a current introduction terminal 31c. The outer electrode 15 is electrically connected to the electrode 133a via the electrode holder portion 137, and is electrically connected to the chamber 131 via the electrode holder portion 137 and the wirings 137a. The outer electrode 15, the electrode holder portion 137, the wirings 137a, and the chamber 131 are at the ground potential. The pulse power module 143 is electrically connected to the peaking capacitor 31a and the preionization capacitor 31b so that, when the switch 143a of the pulse power module 143 is turned ON, charges stored in the charging capacitor (not shown) of the pulse power module 143 are transferred to the peaking capacitor 31a and the preionization capacitor 31b. Further, a voltage is applied between the outer electrode 15 and the inner electrode 13 so that the potential of the outer electrode 15 becomes higher than the potential of the inner electrode 13.

### 2.2 Operation

Next, operation of the gas laser device 100 of the comparative example will be described.

Before the gas laser device 100 outputs the laser light, the internal spaces of the optical path pipes 147a, 171, 500 and the internal spaces of the housings 145a, 161 are filled with a purge gas from the purge gas supply source (not shown). Further, a laser gas is supplied to the internal space of the chamber 131 from the laser gas supply source (not shown). When the laser gas is supplied, the laser processor 190 controls the motor 149a to rotate the cross flow fan 149. By the rotation of the cross flow fan 149, the laser gas circulates through the internal space of the chamber 131.

Before the gas laser device 100 outputs the laser light, the laser processor 190 receives a signal indicating the target energy Et and a signal indicating the light emission trigger Tr from the exposure processor 230. Then, the laser processor 190 sets the charge voltage to be output from the charger 141 so that the difference ΔE between the energy E of the laser light and the target energy Et is within the allowable range. Further, the laser processor 190 turns ON the switch 143a of the pulse power module 143. Thus, the pulse power module 143 applies a pulse high voltage, from the electric energy charged in the charging capacitor (not shown), between the electrode 133a and the electrode 133b and between the inner electrode 13 and the outer electrode 15. When the high voltage is applied between the inner electrode 13 and the outer electrode 15, corona discharge occurs in the vicinity of the dielectric pipe 11 and the end portion 15a, and ultraviolet light is emitted. When the laser gas between the electrode 133a and the electrode 133b is irradiated with the ultraviolet light, the laser gas between the electrode 133a and the electrode 133b undergoes preionization. After preionization, when the voltage between the electrode 133a and the electrode 133b reaches a breakdown voltage, main discharge between the electrode 133a and the electrode 133b occurs. Then, excimer is generated from the laser medium contained in the laser gas between the electrode 133a and the electrode 133b, and light is emitted when the excimer is dissociated. The light resonates between the grating 145c and the output coupling mirror 147, and is amplified every time it passes through the discharge space at the internal space of the chamber 131, thereby causing laser oscillation. Then, a part of the laser light is transmitted through the output coupling mirror 147 as pulse laser light and travels toward the beam splitter 163.

A part of the laser light traveling to the beam splitter 163 is reflected by the beam splitter 163 and received by the optical sensor 165. The optical sensor 165 measures the energy E of the received laser light, and outputs a signal indicating the energy E to the laser processor 190. The laser processor 190 performs control on the charge voltage so that the difference ΔE between the energy E and the target energy Et is within the allowable range.

### 2.3 Problem

In the gas laser device 100 of the comparative example, when the preionization intensity due to the preionization electrode 10 between the electrode 133a and the electrode 133b is lower than expected, unstable main discharge occurs. As a result, the stability of the energy of the laser light output from the gas laser device 100 may decrease. Accordingly, t there arises a concern that the laser light satisfying the performance required by the exposure apparatus 200 is not output.

Therefore, in each of the following embodiments, the chamber 131 of the gas laser device 100 capable of increasing the preionization intensity is exemplified.

### 3. Description of Chamber of First Embodiment

Next, the chamber 131 of the present embodiment will be described. Any component same as that described above is denoted by an identical reference sign, and duplicate description thereof is omitted unless specific description is needed. Further, in some drawings, a part of a member may be omitted or simplified for easy viewing.

### 3.1 Configuration

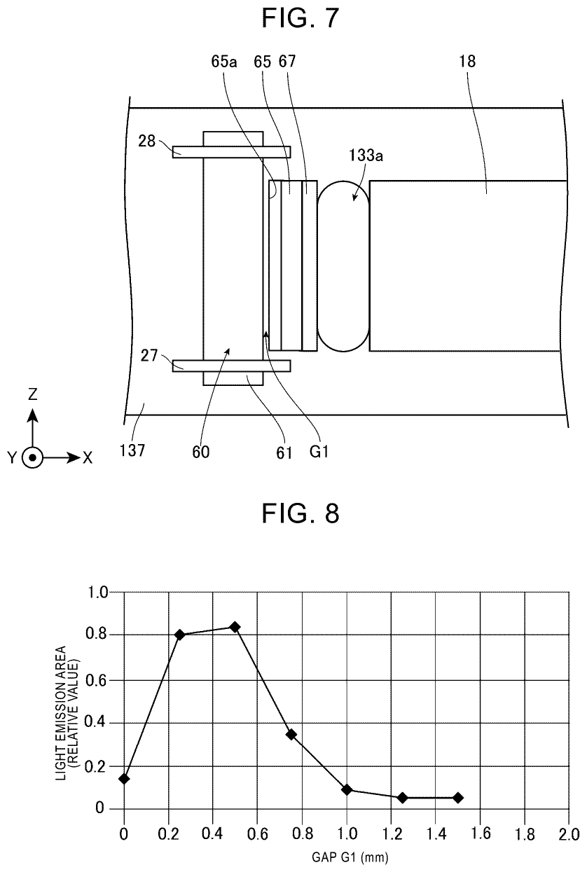

FIG. 6 is a view showing the vicinity of the preionization electrode of the present embodiment along the Z direction, and FIG. 7 is a top view of the vicinity of the preionization electrode shown in FIG. 6. In FIG. 7, the electrode 133b and the electrical insulating portion 135 are not shown for easy viewing. In FIG. 6, the flow of the laser gas is indicated by a bold arrow.

In the chamber 131 of the present embodiment, the configuration of the preionization outer electrode is different from that of the comparative example. In the following, for convenience of explanation, the preionization electrode will be described as a first preionization electrode. Here, the first preionization electrode may be referred to as a preionization electrode 60. The preionization electrode 60 corresponds to the preionization electrode 10 of the comparative example, and is simply changed in sign.

For convenience of explanation, the dielectric pipe, the preionization inner electrode, the preionization outer electrode, and the end portion of the preionization electrode 60 will be described as a first dielectric pipe, a first preionization inner electrode, a first preionization outer electrode, and a first end portion, respectively. In the following, those of the preionization electrode 60 may be referred to as a dielectric pipe 61, an inner electrode 63, an outer electrode 65, and a first end portion 65a, respectively. Further, the guide 17 may be referred to as a first guide 67.

Unlike the comparative example, the first end portion 65a of the present embodiment is spaced apart from the dielectric pipe 61 and faces the dielectric pipe 61 with a first gap G1 with respect thereto. FIG. 8 is a graph showing a simulation result of the relationship between the dimension of the first gap G1 and a light emission area of ultraviolet light between the dielectric pipe 61 and the first end portion 65a. In the simulation, the potential of the inner electrode 63 is-5 kV, the potential of the outer electrode 65 is 0 V, and the region where the electric field strength is 5 kV/mm or more corresponds to the light emission area of the ultraviolet light. The above values of the potential of the inner electrode 63 and the potential of the outer electrode 65 are typical values with which corona discharge occurs in the vicinity of the dielectric pipe 61 and the first end portion 65a. The potential of the inner electrode 63 and the potential of the outer electrode 65 for obtaining the simulation result shown in FIG. 8 are not particularly limited as long as corona discharge occurs. In FIG. 8, the horizontal axis represents the dimension of the first gap G1, and the vertical axis represents the light emission area. The light emission area is indicated as a relative value. With the dimensions of the first gap G1 of 0 mm, 0.25 mm, 0.5 mm, 0.75 mm, 1 mm, 1.25 mm, and 1.5 mm, the light emission areas were 0.13, 0.81, 0.84, 0.34, 0.09, 0.05, and 0.05, respectively. As described above, it can be seen that the light emission area becomes larger with an increase of the dimension of the first gap G1 to be larger than 0 mm. Further, it can be seen that, when the dimension of the first gap G1 is larger than about 0.5 mm, the light emission area becomes smaller from 0.84, which is the maximum value of the light emission area. It can be seen that the light emission area when the dimension of the first gap G1 is about 0.9 mm is larger than the light emission area when the dimension of the first gap G1 is 0 mm. Further, it can be seen that the light emission area when the dimension of the first gap G1 is larger than about 0.9 mm is smaller than the light emission area when the dimension of the first gap G1 is 0 mm. Therefore, when the first gap G1 is larger than 0 mm and equal to or smaller than about 0.9 mm, the light emission area is larger than that of the comparative example in which the first gap G1 is 0 mm as the first end portion 65a being in contact with the dielectric pipe 61. The first gap G1 of the present embodiment is larger than 0 mm and equal to or smaller than about 0.9 mm over the entire length in the Z direction. In this case, the light emission area is about 6.5 times at most as compared with that of the comparative example. Here, it is only required that at least a part of the first gap G1 is larger than 0 mm and equal to or smaller than about 0.9 mm. Further, it is preferable that at least a part of the first gap G1 is equal to or larger than about 0.2 mm and equal to or smaller than about 0.6 mm. In this case, since the light emission area is about 0.65 with the first gap G1 being about 0.2 mm or about 0.6 mm, the light emission area is about 5.0 times or more as compared with the case of the comparative example, and is about 0.8 times the maximum value of the light emission area.

### 3.2 Effect

When the high voltage is applied between the inner electrode 63 and the outer electrode 65, corona discharge occurs in the vicinity of the dielectric pipe 61 and the first end portion 65a, and ultraviolet light is emitted. When the laser gas between the electrode 133a and the electrode 133b is irradiated with the ultraviolet light, the laser gas between the electrode 133a and the electrode 133b undergoes preionization. After preionization, when the voltage between the electrode 133a and the electrode 133b reaches a breakdown voltage, main discharge between the electrode 133a and the electrode 133b occurs. In the chamber 131 of the present embodiment, the first end portion 65a faces the dielectric pipe 61 with the first gap G1 with respect thereto, and at least a part of the first gap G1 is larger than 0 mm and equal to or smaller than 0.9 mm. With the first gap G1 as described above, the light emission area of the ultraviolet light between the dielectric pipe 61 and the first end portion 65a can be increased and the light amount of the ultraviolet light can be increased, as compared with the case in which the first gap G1 is not provided and the case in which the first gap G1 is larger than 0.9 mm. As a result, the preionization intensity can be increased, and a decrease in the stability of the laser light output from the gas laser device 100 can be suppressed. Therefore, the laser light satisfying the performance required by the exposure apparatus 200 can be output.

Further, in the chamber 131, the first gap G1 is larger than 0 mm and equal to or smaller than 0.9 mm over the entire length of the dielectric pipe 61 in the longitudinal direction. According to this configuration, the light emission area of the ultraviolet light between the dielectric pipe 61 and the first end portion 65a can be increased and the light amount of the ultraviolet light can be increased, as compared with the case in which only a part of the first gap G1 is larger than 0 mm and equal to or smaller than 0.9 mm. As a result, the preionization intensity can be further increased, and a decrease in the stability of the laser light output from the gas laser device 100 can be further suppressed.

Further, in the chamber 131, at least a part of the first gap G1 is equal to or larger than 0.2 mm and equal to or smaller than 0.6 mm. According to this configuration, the light emission area is about 5.0 times or more and about 6.5 times or less as compared with the comparative example, and the light emission area of the ultraviolet light between the dielectric pipe 61 and the first end portion 65a can be increased and the light amount of the ultraviolet light can be increased, as compared with the case in which at least a part of the first gap G1 is larger than 0 mm and smaller than 0.2 mm and the case in which at least a part of the first gap G1 is larger than 0.6 mm. As a result, the preionization intensity can be further increased, and a decrease in the stability of the laser light output from the gas laser device 100 can be further suppressed.

The first gap G1 is preferably uniform over the entire length of the dielectric pipe 61 in the longitudinal direction. When the first gap G1 is not uniform, one of the maximum value and the minimum value of the first gap G1 is preferably 0.8 times or more and 1.2 times or less of the other. Further, the preionization electrode 60 of the present embodiment may be arranged downstream of the laser gas flowing between the electrode 133a and the electrode 133b in the X direction, with respect to the electrode 133a. In the present embodiment, the first main electrode is the electrode 133a, the second main electrode is the electrode 133b, and the preionization electrode 60 is arranged beside the electrode 133a, which is the first main electrode. However, the first main electrode may be the electrode 133b, the second main electrode may be the electrode 133a, and the preionization electrode 60 may be arranged beside the electrode 133b, which is the first main electrode.

FIG. 9 is an electrical circuit diagram of the chamber 131 of a first modification of the present embodiment. The inner electrode 63 is connected to the positive side of an external pulse power source 144 via the current introduction terminal 31c. The outer electrode 65 is connected to the negative side of the pulse power source 144.

When corona discharge occurs at the first gap G1 between the dielectric pipe 61 and the first end portion 65a with the first gap G1 provided, ions are generated by the corona discharge and are moved by an electric field in the first gap G1. Examples of the ions include negative ions of fluorine. Such fluorine ions move to the positive side, that is, toward the outer electrode 65 when the circuit diagram remains as in the comparative example shown in FIG. 5. Since fluorine is corrosive, when fluorine ions move to the surface of the outer electrode 65, corrosion of the outer electrode 65 may progress. In the circuit diagram of the present modification, the inner electrode 63 is connected to the positive side of the pulse power source 144 via the current introduction terminal 31c, and a voltage is applied between the outer electrode 65 and the inner electrode 63 so that the potential of the outer electrode 65 is lower than the potential of the inner electrode 63. Therefore, the fluorine ions move toward the inner electrode 63, that is, toward the dielectric pipe 61. Therefore, corrosion of the outer electrode 65 due to fluorine ions can be suppressed. Since the dielectric pipe 61 is made of alumina ceramics or sapphire, it is resistant to fluorine. Therefore, corrosion of the dielectric pipe 61 due to fluorine ions can also be suppressed.

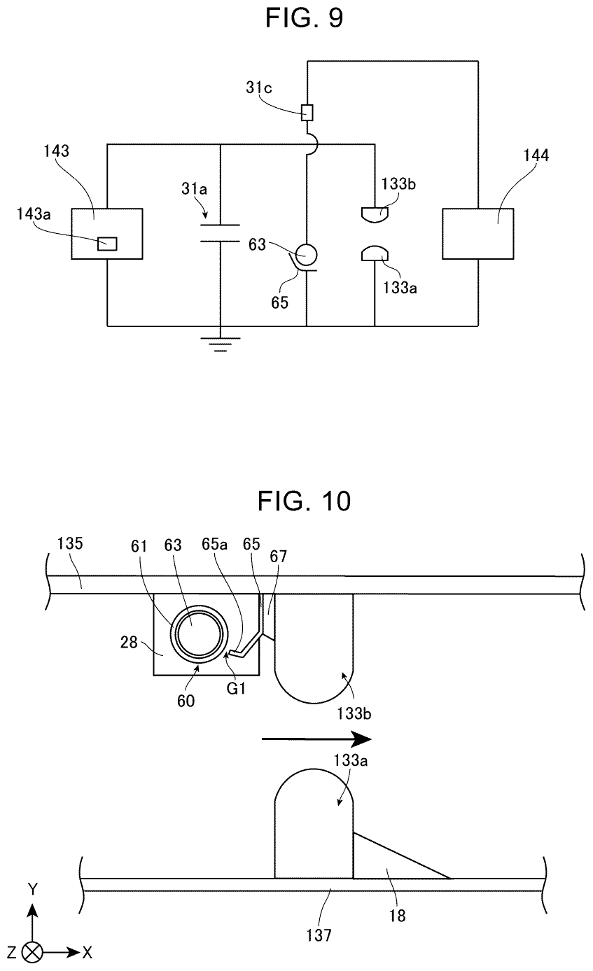

FIG. 10 is a view showing the vicinity of the preionization electrode 60 in a second modification of the present embodiment the the along Z direction. In preionization electrode 60 of the present modification, the arrangement position of the preionization electrode 60 is different from that of the first embodiment. The preionization electrode 60 of the present modification is provided beside the electrode 133b, which is the second main electrode, on one side thereof in the X direction. The preionization electrode 60 of the present modification is also arranged upstream of the laser gas flowing between the electrode 133a and the electrode 133b in the X direction. In FIG. 10, the flow of the laser gas is indicated by a bold arrow.

The first guide 67 of the present modification is fixed to the electrode 133b on a surface of the electrical insulating portion 135 on a side facing the internal space of the chamber 131. Therefore, the outer electrode 65 is fixed to the electrode 133b via the first guide 67. Here, the outer electrode 65 may be directly fixed to the electrode 133b.

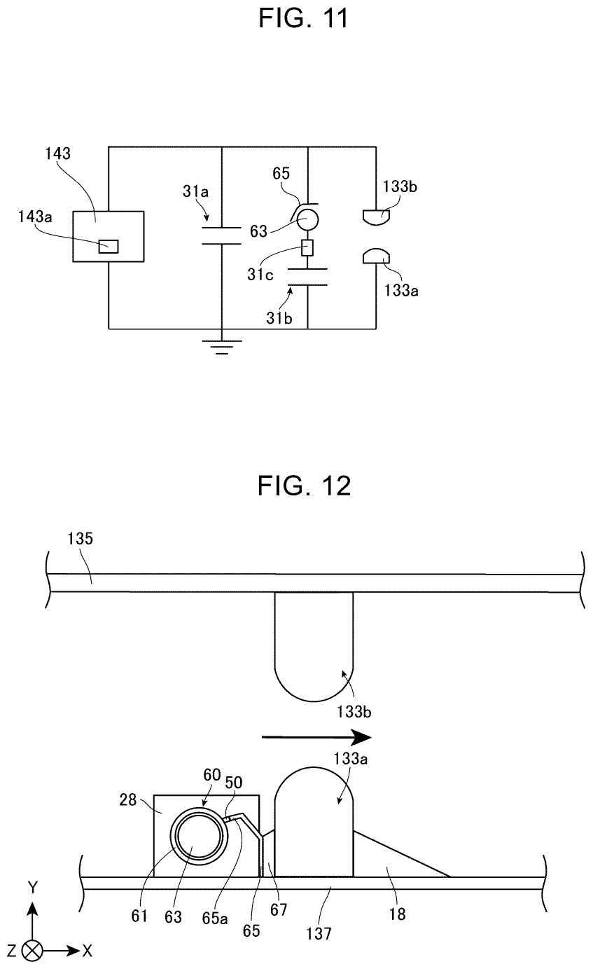

FIG. 11 is an electrical circuit diagram of the chamber 131 according to the second modification of the present embodiment. The outer electrode 65 is electrically connected to the electrode 133b and the pulse power module 143. The inner electrode 63 is electrically connected to one end of the preionization capacitor 31b via the current introduction terminal 31c. The preionization capacitor 31b is connected to the ground potential.

In the present modification as well, a voltage is applied between the outer electrode 65 and the inner electrode 63 so that the potential of the outer electrode 65 becomes lower than the potential of the inner electrode 63. Accordingly, the fluorine ions move toward the inner electrode 63, that is, toward the dielectric pipe 61. Therefore, corrosion of the outer electrode 65 due to fluorine ions can be suppressed.

Here, the preionization electrode 60 of the present modification may be arranged downstream of the laser gas flowing between the electrode 133b and the electrode 133a in the X direction.

### 4. Description of Chamber of Second Embodiment

Next, the chamber 131 of the present embodiment will be described. Any component same as that described above is denoted by an identical reference sign, and duplicate description thereof is omitted unless specific description is needed. Further, in some drawings, a part of a member may be omitted or simplified for easy viewing.

### 4.1 Configuration

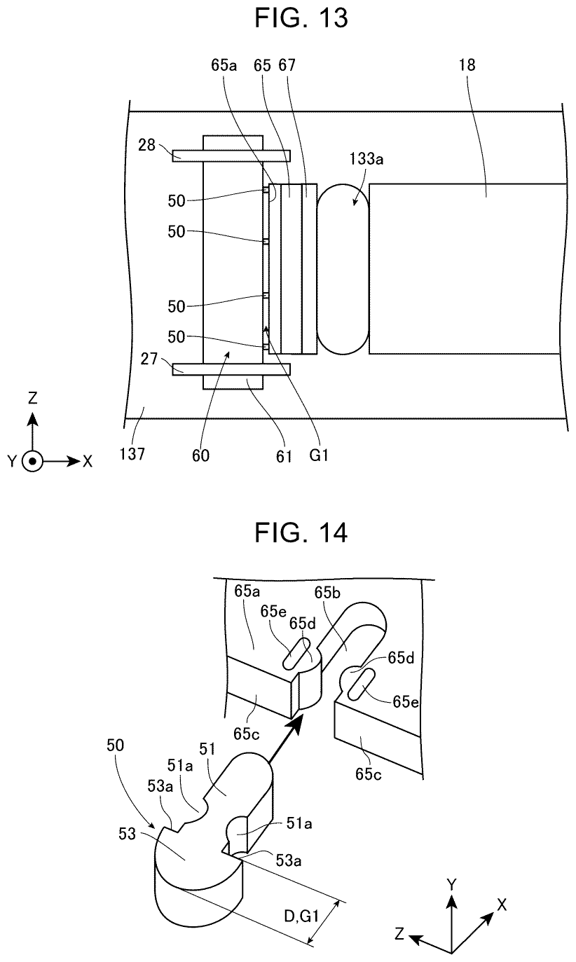

FIG. 12 is a view showing the vicinity of the preionization electrode 60 of the present embodiment along the Z direction, and FIG. 13 is a top view of the vicinity of the preionization electrode 60 shown in FIG. 12. In FIG. 13, the electrode 133b and the electrical insulating portion 135 are not shown for easy viewing.

In the preionization electrode 60 of the present embodiment, the configuration of the preionization electrode 60 is different from that of the first embodiment. The preionization electrode 60 of the present embodiment further includes a plurality of spacers 50 made of a dielectric material and arranged between the dielectric pipe 61 and the first end portion 65a as being in contact with the dielectric pipe 61 and the first end portion 65a. The spacers 50 are arranged in at least two positions, preferably four or more positions. The spacers 50 are arranged in parallel at predetermined intervals in the Z direction. The spacers 50 are arranged at equal intervals, but may not be arranged at equal intervals. Examples of the material of the spacer 50 include alumina ceramics and sapphire. Therefore, the material of the spacer 50 is the same as that of the dielectric pipe 61.

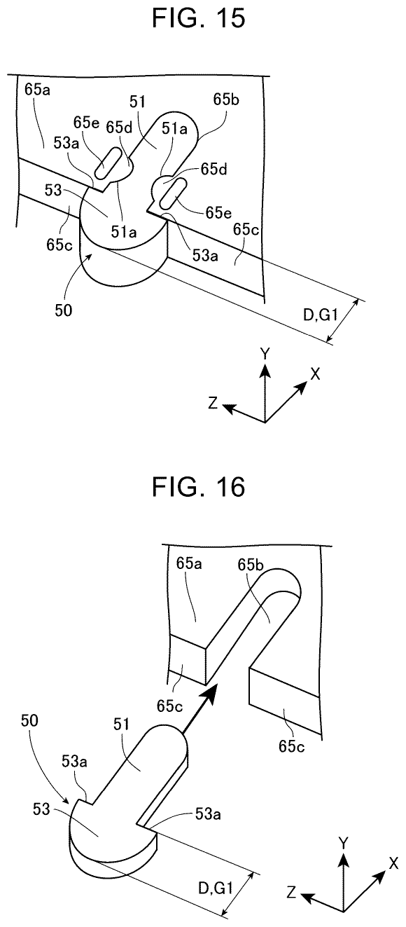

The first end portion 65a of the present embodiment is provided with a plurality of cutouts, and the plurality of spacers 50 are individually fixed to the plurality of cutouts, respectively. The fixing of the above will be described with reference to FIGS. 14 and 15. FIG. 14 is a perspective view of the vicinity of a cutout 65b and the spacer 50 to be fixed to the cutout 65b in the present embodiment. FIG. 15 is a perspective view of the spacer 50 fixed to the cutout 65b shown in FIG. 14. FIGS. 14 and 15 show one spacer 50 and one cutout 65b for clarity.

The cutout 65b is recessed toward the bent side of the first end portion 65a with respect to a surface 65c, facing the dielectric pipe 61, of the first end portion 65a, and penetrates the first end portion 65a in the Y direction. A pair of protrusions 65d facing each other are arranged on the peripheral surface of the cutout 65b. An elongated hole 65e elongated in a direction perpendicular to the surface 65c is arranged beside each protrusion 65d in the first end portion 65a. The elongated hole 65e penetrates the first end portion 65a in the Y direction, and is longer than the protrusion 65d in the direction perpendicular to the surface 65c. The cutout 65b including the protrusion 65d and the elongated hole 65e may be formed by cutting the first end portion 65a with a laser processing machine.

The thickness of the spacer 50 is substantially the same as the thickness of the first end portion 65a in the Y direction. The spacer 50 is inserted and fitted into the cutout 65b along the direction indicated by an arrow in FIG. 14. The spacer 50 includes a root portion 51 to be fitted into the cutout 65b, and a spacer portion 53 to be contacted with the dielectric pipe 61.

On both side surfaces of the root portion 51 facing the cutout 65b, recesses 51a are arranged to be fitted respectively to the protrusions 65d when the root portion 51 is fitted into the cutout 65b. The spacer portion 53 is integrally formed with the root portion 51 and has a semi-cylindrical shape. In the Z direction, the spacer portion 53 is wider than the root portion 51, and the root portion 51 is inserted into the cutout 65b until a back surface 53a of the spacer portion 53 with respect to the dielectric pipe 61 abuts on the surface 65c. At this time, the respective protrusions 65d of the cutout 65b are individually fitted into the respective recesses 51a of the root portion 51. Thus, each of the plurality of spacers 50 is fitted into the corresponding cutout 65b. At this time, the spacer portion 53 protrudes from the cutout 65b toward the dielectric pipe 61, and the curved surface of the spacer portion 53 which is a front surface with respect to the dielectric pipe 61 is in contact with the dielectric pipe 61. When the root portion 51 is being inserted into the cutout 65b, the elongated hole 65e is deformed. As a result, the root portion 51 can be easily inserted into the cutout 65b. A dimension D from the back surface 53a corresponding to the border between the spacer portion 53 and the root portion 51 to the distal end of the spacer portion 53 corresponds to the dimension of the first gap G1. That is, by adjusting the dimension D, the dimension of the first gap G1 is adjusted.

### 4.2 Effect

When the dimension of the first gap G1 is uneven in the Z direction, corona discharge tends to concentrate to a part having a smaller dimension of the first gap G1 than a part having a larger dimension thereof. As a result, the lifetime of the first end portion 65a may be shortened due to wearing to occur at the first end portion 65a more likely in the vicinity of the part having a smaller dimension of the first gap G1 than in the vicinity of the part having a larger dimension of the first gap G1. However, in the chamber 131 of the present embodiment, the plurality of spacers 50 are provided in contact with the dielectric pipe 61 and the first end portion 65a. As a result, unevenness in the dimension of the first gap G1 in the Z direction can be suppressed, partial wearing of the first end portion 65a can be suppressed, and shortening of the lifetime of the first end portion 65a can be suppressed. Here, the plurality of spacers 50 are not necessarily provided.

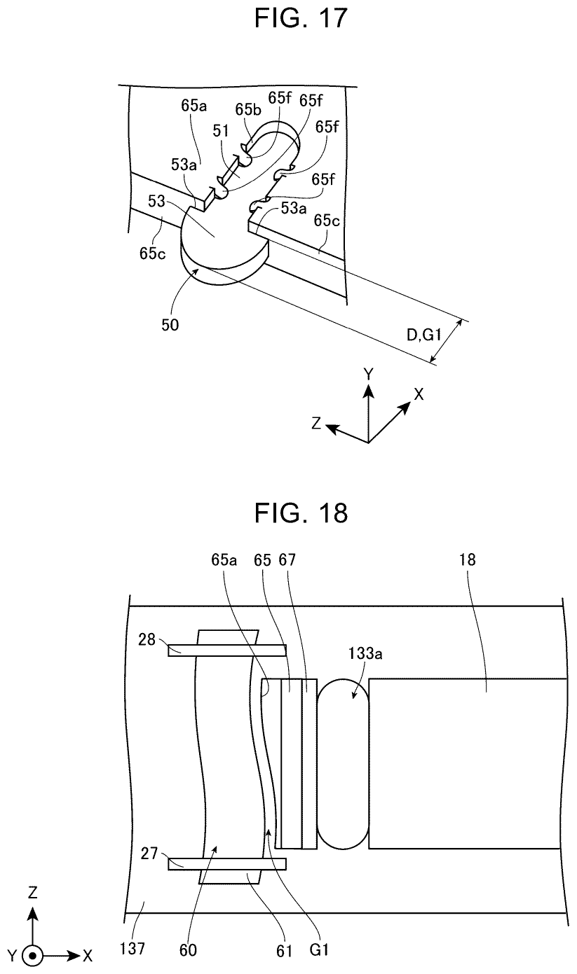

In the present embodiment, each spacer 50 is individually fixed to the corresponding cutout 65b by fitting, but the fixing is not limited thereto, and modifications of the fixing will be described with reference to FIGS. 16 and 17. FIG. 16 is a perspective view of the vicinity of the cutout 65b and the spacer 50 before the fixing according to the present modification. FIG. 17 is a perspective view of the spacer 50 fixed to the cutout 65b according to the present modification. FIGS. 16 and 17 show one spacer 50 and one cutout 65b for clarity.

The first end portion 65a of the present modification differs from the second embodiment in that the cutout 65b is not provided with the protrusion 65d and the elongated hole 65e is not provided. Further, the spacer 50 of the present modification differs from the second embodiment in that the root portion 51 is not provided with the recess 51a and the spacer 50 is thinner than the first end portion 65a in the Y direction. Each spacer 50 of the present modification is individually crimped to the first end portion 65a at the corresponding cutout 65b. Specifically, with respect to the spacer 50 inserted to the cutout 65b, a pressure is applied to a part of the front surface of the first end portion 65a from a direction perpendicular to the front surface, so that a part of the front surface of the first end portion 65a around the cutout 65b protrudes toward the cutout 65b in the planar direction of the front surface of the first end portion 65a, and a part of the front surface is crushed toward the root portion 51. Thus, the protruding portions 65f are provided on the front surface. FIG. 17 shows an example in which four protruding portions 65f are provided, which are located at four positions different from each other. Also, on the rear surface of the first end portion 65a, protruding portions (not shown) are provided similarly to the front surface of the first end portion 65a. The protruding portions on the rear surface, the number of which is the same as the number of the protruding portions 65f on the front surface, face the protruding portions 65f via the root portion 51. The spacer 50 is fixed to the first end portion 65a owing to that the root portion 51 is sandwiched between the protruding portions 65f on the front surface and the protruding portions on the rear surface.

According to the chamber 131 of the present modification, the configuration of each of the first end portion 65a and the spacer 50 can be simplified as compared with a case in which the protrusions 65d and the elongated holes 65e are provided on the first end portion 65a and the recesses 51a are provided in each spacer 50. Here, the number of the protruding portions 65f is not particularly limited. Further, the number of the protruding portions on the rear surface may not be the same as the number of the protruding portions 65f. Further, in the fixing of the spacer 50, each of the plurality of spacers 50 may be individually fixed to the plurality of cutouts 65b by press-fitting.

### 5. Description of Chamber of Third Embodiment

Next, the chamber 131 of the present embodiment will be described. Any component same as that described above is denoted by an identical reference sign, and duplicate description thereof is omitted unless specific description is needed. Further, in some drawings, a part of a member may be omitted or simplified for easy viewing.

### 5.1 Configuration

FIG. 18 is a top view of the vicinity of the preionization electrode 60 of the present embodiment. In FIG. 18, the electrode 133b and the electrical insulating portion 135 are not shown for easy viewing.

In the preionization electrode 60 of the present embodiment, the configuration of the preionization electrode 60 is different from that of the first embodiment. When the dielectric pipe 61 is made of alumina ceramics or sapphire, there may be a case in which the straightness of the dielectric pipe 61 is lowered, the dielectric pipe 61 is bent, and undulation occurs on the outer circumference surface of the dielectric pipe 61. In FIG. 18, the undulation is illustrated excessively large for easy viewing. When the dielectric pipe 61 having a high straightness is to be manufactured in order to suppress the undulation, an extra cost may be required. Further, although it is conceivable to select a dielectric pipe 61 having a high straightness from the plurality of finished dielectric pipes 61, the yield may be reduced, which may lead to an increase in cost. When an attempt is made to suppress the undulation by polishing the outer circumference surface of the dielectric pipe 61, a large amount of microcracks may be generated on the outer circumference surface of the dielectric pipe 61, and the electrical dielectric strength of the dielectric pipe 61 may decrease. When the dielectric pipe 61 having a low straightness is inevitably used as described above, the dimension of the first gap G1 may be uneven in the Z direction.

Therefore, the first end portion 65a of the present embodiment is formed along the undulation of the outer circumference surface of the dielectric pipe 61 at a region where the first end portion 65a faces. The undulation at the region is measured by a three-dimensional measurement instrument, and the first end portion 65a is processed in accordance with the measured undulation amount. In the processing, the first end portion 65a is processed according to the undulation amount with reference to the most recessed part of the region.

### 5.2 Effect

When undulation occurs on the outer circumference surface of the dielectric pipe 61, the dimension of the first gap G1 may be uneven in the Z direction. When the dimension of the first gap G1 is uneven in the Z direction, corona discharge tends to concentrate to a part having a smaller dimension of the first gap G1 than a part having a larger dimension thereof. As a result, the lifetime of the first end portion 65a may be shortened due to wearing to occur at the first end portion 65a more likely in the vicinity of the part having a smaller dimension of the first gap G1 than in the vicinity of the part having a larger dimension of the first gap G1. However, according to the chamber 131 of the present embodiment, the first end portion 65a is formed along the undulation of the outer circumference surface of the dielectric pipe 61. As a result, unevenness in the dimension of the first gap G1 in the Z direction can be suppressed, partial wearing of the first end portion 65a can be suppressed, and shortening of the lifetime of the first end portion 65a can be suppressed.

Here, the first end portion 65a may not be formed along the undulation of the outer circumference surface of the dielectric pipe 61. Further, at the first end portion 65a of the present embodiment, the cutout 65b of the second embodiment or the modification thereof may be provided and the spacer 50 in the second embodiment or the modification thereof may be fixed the cutout 65b.

### 6. Description of Chamber of Fourth Embodiment

Next, the chamber 131 of the present embodiment will be described. Any component same as that described above is denoted by an identical reference sign, and duplicate description thereof is omitted unless specific description is needed. Further, in some drawings, a part of a member may be omitted or simplified for easy viewing.

### 6.1 Configuration

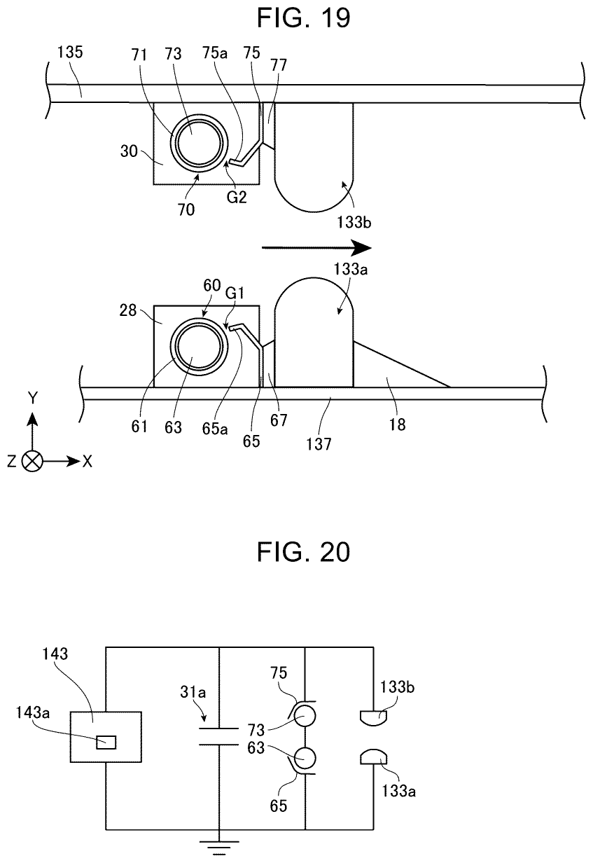

FIG. 19 is a view showing the vicinity of the preionization electrode of the present embodiment along the Z direction.

The chamber 131 of the present embodiment differs from that of the first embodiment in that another preionization electrode is added to the first embodiment. In the following, for convenience of explanation, the added preionization electrode will be described as a second preionization electrode. The second preionization electrode may be referred to as a preionization electrode 70. The preionization electrode 70 corresponds to the preionization electrode 60 in the second modification of the first embodiment, and is simply changed in sign and has the same configuration as the preionization electrode 60.

For convenience of explanation, the dielectric pipe, the preionization inner electrode, the preionization outer electrode, and the end portion of the preionization electrode 70 will be described 75a as a second dielectric pipe, a second preionization inner electrode, a second preionization outer electrode, and a second end portion. In the following, those of the preionization electrode 70 may be referred to as a dielectric pipe 71, an inner electrode 73, an outer electrode 75, and a second end portion 75a.

The preionization electrode 70 is provided at a position facing the preionization electrode 60 beside the electrode 133b. The preionization electrodes 60, 70 are arranged upstream of the laser gas flowing between the electrode 133a and the electrode 133b in the X direction. In FIG. 19, the flow of the laser gas is indicated by a bold arrow.

Since the preionization electrode 70 has the same configuration as the preionization electrode 60, the second end portion 75a faces the dielectric pipe 71 with a second gap G2 with respect thereto. The relationship between the dimension of the second gap G2 in the present embodiment and the light emission area of the ultraviolet light between the dielectric pipe 71 and the second end portion 75a is the same as the relationship shown in FIG. 8. The second gap G2 is larger than 0 mm and equal to or smaller than 0.9 mm over the entire length in the Z direction. Here, it is only required that at least a part of the second gap G2 is larger than 0 mm and equal to or smaller than 0.9 mm. Further, it is preferable that at least a part of the second gap G2 is equal to or larger than 0.2 mm and equal to or smaller than 0.6 mm. The second gap G2 is preferably the same as the first gap G1.

A second guide 77 having the same configuration as the first guide 67 of the second modification of the first embodiment is arranged on a surface of the electrical insulating portion 135 of the present embodiment on a side facing the internal space of the chamber 131. Therefore, the outer electrode 75 is fixed to the electrode 133b via the second guide 77. Here, the outer electrode 75 may be directly fixed to the electrode 133b.

A holder (not shown) having the same configuration as the holder 27 and a holder 30 having the same configuration as the holder 27 are provided on the surface of the electrical insulating portion 135 of the present embodiment on the side facing the internal space of the chamber 131. Similarly to the holding of the dielectric pipe 61 by the holders 27, 28, one end side of the dielectric pipe 71 is inserted to a hole of a holder (not shown) and held by the holder, and the other end side of the dielectric pipe 71 is inserted to a hole (not shown) of the holder 30 and held by the holder 30.

One end of the inner electrode 63 and one end of the inner electrode 73 are electrically connected to each other by an inner electrode connector (not shown). The other end of the inner electrode 63 and the other end of the inner electrode 73 may also be electrically connected to each other by an inner electrode connector. The inner electrode connector has a cylindrical shape, but may have a wire shape. The other end of the outer electrode 75 is electrically connected to the electrode 133b.

FIG. 20 is an electrical circuit diagram of the chamber 131 according to the present embodiment. The electrical circuit diagram of the present embodiment differs from the electrical circuit diagram of the comparative embodiment in that the preionization capacitor 31b and the current introduction terminal 31c are not arranged. When the switch 143a is turned ON, charges stored in the charging capacitor are transferred to the peaking capacitor 31a, and at the same time, the voltage between the electrode 133a and the electrode 133b increases. Further, a half of the voltage between the electrode 133a and the electrode 133b is induced in each of the inner electrodes 63, 73. Accordingly, corona discharge occurs in the vicinity of the dielectric pipe 61 and the first end portion 65a and in the vicinity of the dielectric pipe 71 and the second end portion 75a, and ultraviolet light is emitted from each of them. When the laser gas between the electrode 133a and the electrode 133b is irradiated with the ultraviolet light, the laser gas between the electrode 133a and the electrode 133b undergoes preionization. After preionization, when the voltage between the electrode 133a and the electrode 133b reaches a breakdown voltage, main discharge between the electrode 133a and the electrode 133b occurs. Then, excimer is generated from the laser medium contained in the laser gas between the electrode 133a and the electrode 133b, and light is emitted when the excimer is dissociated.

### 6.2 Effect

In the chamber 131 of the present embodiment, the second end portion 75a faces the dielectric pipe 71 with the second gap G2 with respect thereto, and at least a part of the second gap G2 is larger than 0 mm and equal to or smaller than 0.9 mm. With the second gap G2 as described above, the light emission area of the ultraviolet light between the dielectric pipe 71 and the second end portion 75a can be increased and the light amount of the ultraviolet light can be increased, as compared with the case in which the second gap G2 is not provided and the case in which the second gap G2 is larger than 0.9 mm. As a result, the preionization intensity can be increased, and a decrease in the stability of the laser light output from the gas laser device 100 can be suppressed. Therefore, the laser light satisfying the performance required by the exposure apparatus 200 can be output.

### 7. Description of Chamber of Fifth Embodiment

Next, the chamber 131 of the present embodiment will be described. Any component same as that described above is denoted by an identical reference sign, and duplicate description thereof is omitted unless specific description is needed. Further, in some drawings, a part of a member may be omitted or simplified for easy viewing.

### 7.1 Configuration

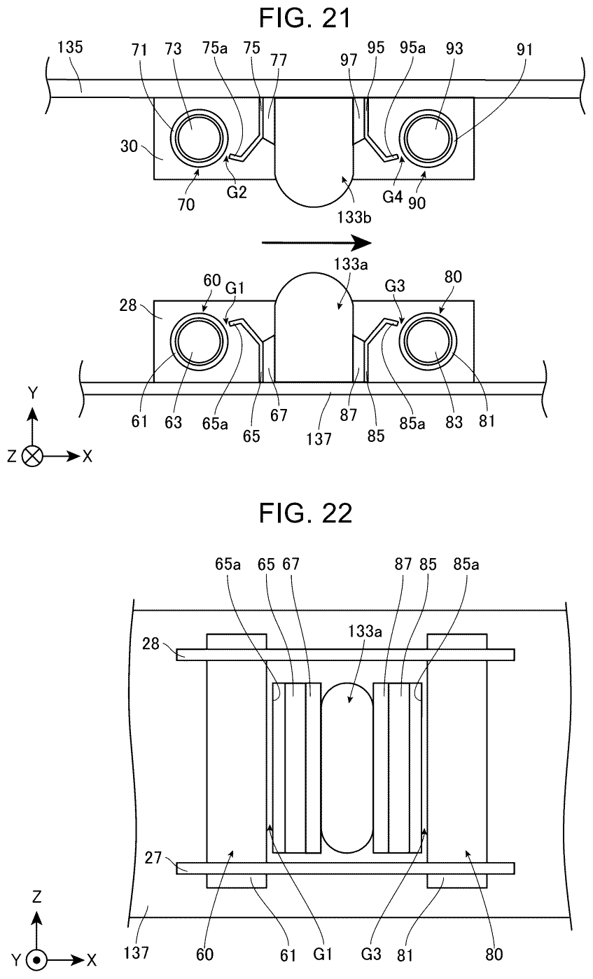

FIG. 21 is a view showing the vicinity of the preionization electrodes 60, 70 of the present embodiment along the Z direction, and FIG. 22 is a top view of the vicinity of the preionization electrode 60 shown in FIG. 21. In FIG. 22, the electrode 133b, the preionization electrode on the electrode 133b side, and the electrical insulating portion 135 are not shown for easy viewing.

The chamber 131 of the present embodiment differs from that of the fourth embodiment in that two preionization electrodes are further added to the fourth embodiment. For convenience of explanation, each of the two added preionization electrodes will be described as a third preionization electrode and a fourth preionization electrode. The third preionization electrode may be referred to as a preionization electrode 80, and the fourth preionization electrode may be referred to as a preionization electrode 90.

Each of the preionization electrodes 80, 90 has the same configuration as the preionization electrode 60, while the preionization electrode 80 is arranged beside the electrode 133a and the preionization electrode 90 is arranged beside the electrode 133b.

For convenience of explanation, the dielectric pipe, the preionization inner electrode, the preionization outer electrode, and the end portion of the preionization electrode 80 will be described as a third dielectric pipe, a third preionization inner electrode, a third preionization outer electrode, and a third end portion. In the following, those of the preionization electrode 80 may be referred to as a dielectric pipe 81, an inner electrode 83, an outer electrode 85, and a third end portion 85a. Further, the dielectric pipe, the preionization inner electrode, the preionization outer electrode, and the end portion of the preionization electrode 90 will be described as a fourth dielectric pipe, a fourth preionization inner electrode, a fourth preionization outer electrode, and a fourth end portion. In the following, those of the preionization electrode 90 may be referred to as a dielectric pipe 91, an inner electrode 93, an outer electrode 95, and a fourth end portion 95a.

The preionization electrode 80 is arranged beside the electrode 133a on the other side thereof in the X direction, that is, on a side opposite to the preionization electrode 60. Further, the preionization electrode 90 is arranged beside the electrode 133b on the other side thereof, that is, on a side opposite to the preionization electrode 70, and at a position facing the preionization electrode 80. The preionization electrode 80 and the preionization electrode 90 are arranged downstream of the laser gas flowing between the electrode 133a and the electrode 133b in the X direction. In FIG. 21, the flow of the laser gas is indicated by a bold arrow.

Since each of the preionization electrodes 80, 90 has the same configuration as the preionization electrode 60, the third end portion 85a faces the dielectric pipe 81 with the third gap G3 with respect thereto, and the fourth end portion 95a faces the dielectric pipe 91 with the fourth gap G4 with respect thereto. The relationship between the dimension of the third gap G3 in the present embodiment and the light emission area of the ultraviolet light between the dielectric pipe 81 and the third end portion 85a is the same as the relationship shown in FIG. 8. Further, the relationship between the dimension of the fourth gap G4 and the light emission area is the same as the relationship shown in FIG. 8. Each of the third gap G3 and the fourth gap G4 is larger than 0 mm and is equal to or smaller than 0.9 mm over the entire length in the Z direction. Here, it is only required that at least a part of each of the third gap G3 and the fourth gap G4 is larger than 0 mm and equal to or smaller than 0.9 mm. Further, it is preferable that at least a part of each of the third gap G3 and the fourth gap G4 is preferably equal to or larger than 0.2 mm and equal to or smaller than 0.6 mm. The third gap G3 is preferably the same as the first gap G1 or the second gap G2. Further, the fourth gap G4 is preferably the same as the first gap G1, the second gap G2, or the third gap G3.

The electrode holder portion 137 of the present embodiment is provided with a third guide 87 having the same configuration as the first guide 67 and fixed to the electrode 133a. Further, a fourth guide 97 having the same configuration as the second guide 77 and fixed to the electrode 133b is provided on a surface of the electrical insulating portion 135 on a side facing the internal space of the chamber 131. Each of the outer electrodes 85, 95 is individually fixed to the guides 87, 97 in the same manner as the fixing of the outer electrodes 65, 75 to the guides 67, 77. Therefore, the outer electrode 85 is fixed to the electrode 133a via the third guide 87, and the outer electrode 95 is fixed to the electrode 133b via the fourth guide 97. Here, the outer electrode 85 may be directly fixed to the electrode 133a, and the outer electrode 95 may be directly fixed to the electrode 133b.

Each of the holders 27, 28 of the present embodiment extends in the X direction, and includes a hole (not shown) at each of the upstream side and the downstream side of the flow of the laser gas. One end side of the dielectric pipe 61 is inserted to the hole of the holder 27 on the upstream side, and one end side of the dielectric pipe 81 is inserted to the hole of the holder 27 on the downstream side. Thus, one end side of the dielectric pipe 61 and one end side of the dielectric pipe 81 are held by the holder 27. Further, the other end side of the dielectric pipe 61 is inserted to the hole of the holder 28 on the upstream side, and the other end side of the dielectric pipe 81 is inserted to the hole of the holder 28 on the downstream side. Accordingly, the other end side of the dielectric pipe 61 and the other end side of the dielectric pipe 81 are held by the holder 28.

Each of the holder (not shown) and the holder 30 of the present embodiment extends in the X direction, and includes a hole (not shown) at each of the upstream side and the downstream side of the flow of the laser gas. One end side of the dielectric pipe 71 is inserted to the hole of the holder (not shown) on the upstream side, and one end side of the dielectric pipe 91 is inserted to the hole of the holder (not shown) on the downstream side. Thus, one end side of the dielectric pipe 71 and one end side of the dielectric pipe 91 are held by the holder (not shown). Further, the other end side of the dielectric pipe 71 is inserted to the hole of the holder 30 on the upstream side, and the other end side of the dielectric pipe 91 is inserted to the hole of the holder 30 on the downstream side. Thus, the other end side of the dielectric pipe 71 and the other end side of the dielectric pipe 91 are held by the holder 30.

One end of the inner electrode 83 and one end of the inner electrode 93 are electrically connected to each other by an inner electrode connector having the same configuration as the inner electrode connector for the inner electrodes 63, 73. The other end of the inner electrode 83 and the other end of the inner electrode 93 may also be electrically connected to each other by an inner electrode connector. The other end of the outer electrode 85 is electrically connected to the electrode 133a via the electrode holder portion 137, and is electrically connected to the chamber 131 via the electrode holder portion 137 and the wirings 137a. The outer electrode 85, the electrode holder portion 137, the wirings 137a, and the chamber 131 are at the ground potential. The other end of the outer electrode 95 is electrically connected to the electrode 133b.

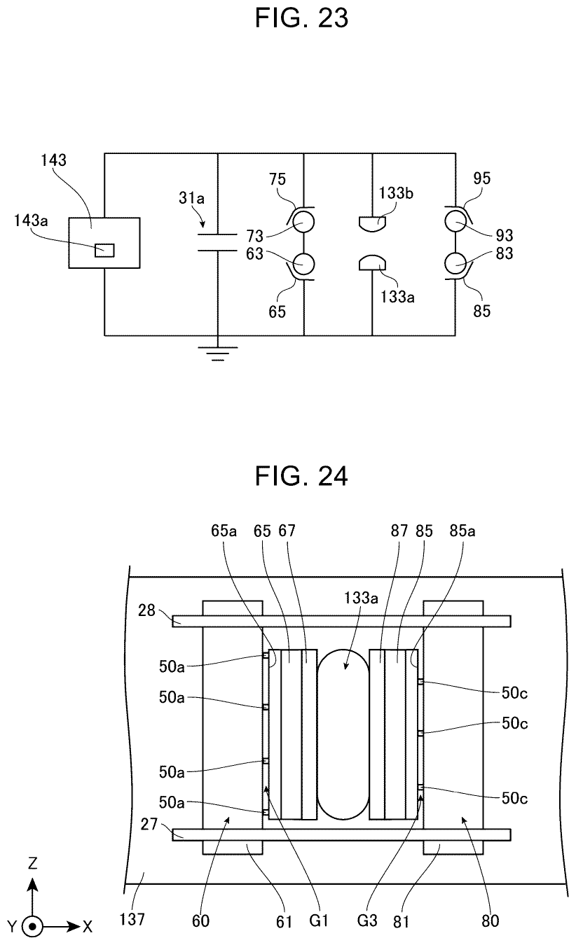

FIG. 23 is an electrical circuit diagram of the chamber 131 according to the present embodiment. When the switch 143a is turned ON, charges stored in the charging capacitor are transferred to the peaking capacitor 31a, and at the same time, the voltage between the electrode 133a and the electrode 133b increases. Further, a half of the voltage between the electrode 133a and the electrode 133b is induced in each of the inner electrodes 63, 73, 83, 93. Accordingly, corona discharge occurs in the vicinity of the dielectric pipe 61 and the first end portion 65a, in the vicinity of the dielectric pipe 71 and the second end portion 75a, in the vicinity of the dielectric pipe 81 and the third end portion 85a, and in the vicinity of the dielectric pipe 91 and the fourth end portion 95a, and ultraviolet light is emitted from each of them. When the laser gas between the electrode 133a and the electrode 133b is irradiated with the ultraviolet light, the laser gas between the electrode 133a and the electrode 133b undergoes preionization. Then, main discharge occurs between the electrode 133a and the electrode 133b. Thus, excimer is generated from the laser medium contained in the laser gas between the electrode 133a and the electrode 133b, and light is emitted when the excimer is dissociated.

### 7.2 Effect

In the chamber 131 of the present embodiment, the third end portion 85a faces the dielectric pipe 81 with the third gap G3 with respect thereto, and the fourth end portion 95a faces the dielectric pipe 91 with the fourth gap G4 with respect thereto. At least a part of each of the third and fourth gaps G3, G4 is larger than 0 mm and is equal to or smaller than 0.9 mm. With the third and fourth gaps G3, G4 as described above, the light emission areas of the ultraviolet light between the dielectric pipe 81 and the third end portion 85a and between the dielectric pipe 91 and the fourth end portion 95a can be increased and the light amount of the ultraviolet light can be increased, as compared with the case in which the third and fourth gaps G3, G4 are not provided and the case in which the third and fourth gaps G3, G4 are larger than 0.9 mm. As a result, the preionization intensity can be increased, and a decrease in the stability of the laser light output from the gas laser device 100 can be suppressed. Therefore, the laser light satisfying the performance required by the exposure apparatus 200 can be output.

Here, in the chamber 131 of the present embodiment, any of the four preionization electrodes 60, 70, 80, 90 may not be arranged.

FIG. 24 is a top view of the vicinity of the preionization electrodes 60, 80 of a modification of the present embodiment. In FIG. 24, the electrode 133b, the preionization electrodes 70, 90 on the electrode 133b side, and the electrical insulating portion 135 are not shown for easy viewing.

Each of the preionization electrode 60 and the preionization electrode 80 of the present modification further includes a plurality of spacers and a plurality of cutouts described in the second embodiment and the modification thereof. For convenience of explanation, FIG. 24 shows the spacers of the preionization electrode 60 as the spacers 50a, and the spacers of the preionization electrode 80 as spacers 50c. The spacers 50a, 50c are arranged alternately along the Z direction. In the present modification, it is preferable that four spacers 50a and three spacers 50c are arranged, and each spacer 50c is arranged substantially in the middle of the corresponding adjacent spacers 50a in the Z direction. Thus, the length between adjacent spacers 50a is approximately the same as the length between adjacent spacers 50c. If the lengths of the above are the same, the spacers 50c may not be arranged substantially in the middle of the corresponding adjacent spacers 50a.

At parts where the spacers 50a, 50c are arranged, electric properties such as permittivity may change, the emission amount of ultraviolet light due to corona discharge decreases, and the emission amount of ultraviolet light may become uneven in the Z direction. When the emission amount of ultraviolet light becomes uneven, main discharge becomes unstable. However, in the present modification, since the spacers 50a, 50c are alternately arranged along the Z direction, unevenness of the emission amount of ultraviolet light in the Z direction can be suppressed. As a result, unstable main discharge can be suppressed, and a decrease in the stability of the energy of the laser light output from the gas laser device 100 can be suppressed. Therefore, the laser light satisfying the performance required by the exposure apparatus 200 can be output.

Here, the numbers of spacers 50a, 50c may be the same, and the spacers 50a, 50c may be arranged adjacent to each other. Further, the number of the spacers 50a on the upstream side of the laser gas may be more or less than the number of the spacers 50c on the downstream side.

Further, in the present modification, the spacers 50 may be arranged in the preionization electrode 70 and the preionization electrode 90 in the same manner as in the preionization electrode 60 and the preionization electrode 80.

The description above is intended to be illustrative and the present disclosure is not limited thereto. Therefore, it would be obvious to those skilled in the art that various modifications to the embodiment of the present disclosure would be possible without departing from the spirit and the scope of the appended claims. Further, it would be also obvious to those skilled in the art that the embodiments of the present disclosure would be appropriately combined. The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. A chamber for a gas laser device having an internal space at which a laser gas is enclosed; the chamber comprising:
a first main electrode and a second main electrode arranged with a longitudinal direction thereof being along a predetermined direction as being apart from and facing each other in the internal space;
a window arranged at a wall surface of the chamber and configured to transmit light from the internal space; and
a first preionization electrode arranged beside one side of the first main electrode,
the first preionization electrode including a first dielectric pipe, a first preionization inner electrode arranged in the first dielectric pipe and extending along a longitudinal direction of the first dielectric pipe, and a first preionization outer electrode extending along the longitudinal direction of the first dielectric pipe and including a first end portion facing the first dielectric pipe with a first gap with respect to the first dielectric pipe, and
at least a part of the first gap being larger than 0 mm and equal to or smaller than 0.9 mm.

2. The chamber for a gas laser device according to claim 1,
wherein the first gap is larger than 0 mm and equal to or smaller than 0.9 mm over an entire length of the first dielectric pipe in the longitudinal direction.

3. The chamber for a gas laser device according to claim 1,
wherein at least a part of the first gap is equal to or larger than 0.2 mm and equal to or smaller than 0.6 mm.

4. The chamber for a gas laser device according to claim 1,
wherein the first preionization electrode further includes a plurality of spacers made of a dielectric material and arranged between the first dielectric pipe and the first end portion as being in contact with the first dielectric pipe and the first end portion.

5. The chamber for a gas laser device according to claim 4,
wherein each of the plurality of spacers is made of a material same as the first dielectric pipe.

6. The chamber for a gas laser device according to claim 4,
wherein each of the plurality of spacers is made of alumina ceramics or sapphire.

7. The chamber for a gas laser device according to claim 4,
wherein the first end portion is provided with a plurality of cutouts, and the plurality of spacers are individually fixed to the plurality of cutouts, respectively.

8. The chamber for a gas laser device according to claim 7,
wherein the plurality of spacers are fitted into the cutouts, respectively.

9. The chamber for a gas laser device according to claim 8,
wherein each of the plurality of spacers includes a recess provided in a side surface facing a peripheral surface of the corresponding cutout, and
each of the plurality of cutouts is provided with a protrusion fitted into the recess.

10. The chamber for a gas laser device according to claim 7,
wherein each of the plurality of spacers is individually crimped to the first end portion at the corresponding cutout.

11. The chamber for a gas laser device according to claim 1,
wherein the first end portion is formed along undulation of an outer circumference surface of the first dielectric pipe.

12. The chamber for a gas laser device according to claim 1,
further comprising a second preionization electrode arranged beside the one side of the second main electrode at a position facing the first preionization electrode,
wherein the second preionization electrode includes a second dielectric pipe, a second preionization inner electrode arranged in the second dielectric pipe and extending along a longitudinal direction of the second dielectric pipe, and a second preionization outer electrode extending along the longitudinal direction of the second dielectric pipe and including a second end portion facing the second dielectric pipe with a second gap with respect to the second dielectric pipe, and
at least a part of the second gap is larger than 0 mm and equal to or smaller than 0.9 mm.

13. The chamber for a gas laser device according to claim 12,
wherein the first preionization inner electrode is electrically connected to the second preionization inner electrode,
the first preionization outer electrode is electrically connected to the first main electrode, and
the second preionization outer electrode is electrically connected to the second main electrode.

14. The chamber for a gas laser device according to claim 12, further comprising:
a third preionization electrode arranged beside the other side of the first main electrode; and
a fourth preionization electrode arranged beside the other side of the second main electrode at a position facing the third preionization electrode,
wherein the third preionization electrode includes a third dielectric pipe, a third preionization inner electrode arranged in the third dielectric pipe and extending along a longitudinal direction of the third dielectric pipe, and a third preionization outer electrode extending along the longitudinal direction of the third dielectric pipe and including a third end portion facing the third dielectric pipe with a third gap with respect to the third dielectric pipe,
the fourth preionization electrode includes a fourth dielectric pipe, a fourth preionization inner electrode arranged in the fourth dielectric pipe and extending along a longitudinal direction of the fourth dielectric pipe, and a fourth preionization outer electrode extending along the longitudinal direction of the fourth dielectric pipe and including a fourth end portion facing the fourth dielectric pipe with a fourth gap with respect to the fourth dielectric pipe, and
at least a part of each of the third gap and the fourth gap is larger than 0 mm and equal to or smaller than 0.9 mm.

15. The chamber for a gas laser device according to claim 14,
wherein the first preionization inner electrode is electrically connected to the second preionization inner electrode,
the third preionization inner electrode is electrically connected to the fourth preionization inner electrode,
the first preionization outer electrode and the third preionization outer electrode are electrically connected to the first main electrode, and
the second preionization outer electrode and the fourth preionization outer electrode are electrically connected to the second main electrode.

16. A gas laser device including a chamber having an internal space at which a laser gas is enclosed,
the chamber including:
a first main electrode and a second main electrode arranged with a longitudinal direction thereof being along a predetermined direction as being apart from and facing each other in the internal space;
a window arranged at a wall surface of the chamber and configured to transmit light from the internal space; and
a first preionization electrode arranged beside one side of the first main electrode,
the first preionization electrode including a first dielectric pipe, a first preionization inner electrode arranged in the first dielectric pipe and extending along a longitudinal direction of the first dielectric pipe, and a first preionization outer electrode extending along the longitudinal direction of the first dielectric pipe and including a first end portion facing the first dielectric pipe with a first gap with respect to the first dielectric pipe, and
at least a part of the first gap being larger than 0 mm and equal to or smaller than 0.9 mm.

17. The gas laser device according to claim 16,
wherein a voltage is applied between the first preionization outer electrode and the first preionization inner electrode such that a potential of the first preionization outer electrode becomes higher than a potential of the first preionization inner electrode.

18. An electronic device manufacturing method, comprising:
generating laser light using a gas laser device including a chamber having an internal space at which a laser gas is enclosed;
outputting the laser light to an exposure apparatus; and
exposing a photosensitive substrate to the laser light in the exposure apparatus to manufacture an electronic device, the chamber including:
a first main electrode and a second main electrode arranged with a longitudinal direction thereof being along a predetermined direction as being apart from and facing each other in the internal space;
a window arranged at a wall surface of the chamber and configured to transmit light from the internal space;
a first preionization electrode arranged beside one side of the first main electrode,
the first preionization electrode including a first dielectric pipe, a first preionization inner electrode arranged in the first dielectric pipe and extending along a longitudinal direction of the first dielectric pipe, and a first preionization outer electrode extending along the longitudinal direction of the first dielectric pipe and including a first end portion facing the first dielectric pipe with a first gap with respect to the first dielectric pipe, and
at least a part of the first gap being larger than 0 mm and equal to or smaller than 0.9 mm.
